(19) United States
(12) Patent Application Publication
(10) Pub. No.: US 2017/0250268 A1
(43) Pub. Date: Aug. 31, 2017

(54) FIN FIELD EFFECT TRANSISTOR AND METHOD FOR FABRICATING THE SAME

(71) Applicant: Taiwan Semiconductor Manufacturing Co., Ltd., Hsinchu (TW)

(72) Inventors: Ru-Shang Hsiao, Hsinchu County (TW); Chii-Ming Wu, Taipei City (TW); Chi-Cherng Jeng, Tainan City (TW)

(21) Appl. No.: 15/054,091

(22) Filed: Feb. 25, 2016

(51) Int. Cl. H01L 29/66; H01L 21/762; H01L 29/10; H01L 29/49; H01L 21/311; H01L 21/283; H01L 29/78; H01L 29/06; H01L 21/306; H01L 21/3213

(52) U.S. Cl. CPC H01L 29/66818; H01L 29/66795; H01L 29/66545; H01L 21/30604; H01L 21/76224; H01L 29/1054; H01L 21/32134; H01L 21/31111; H01L 21/283; H01L 29/1095; H01L 29/785; H01L 29/0653; H01L 29/495; H01L 29/4966

(57) ABSTRACT

A FinFET includes a semiconductor substrate, a plurality of insulators, a gate stack, and a strained material. The semiconductor substrate includes at least one semiconductor fin thereon. The semiconductor fin includes source/drain regions and a channel region, and a width of the source/drain regions is larger than a width of the channel region. The insulators are disposed on the semiconductor substrate and the semiconductor fin is sandwiched by the insulators. The gate stack is located over the channel region of the semiconductor fin and over portions of the insulators. The strained material covers the source/drain regions of the semiconductor fin. In addition, a method for fabricating the FinFET is provided.

### BACKGROUND

As the semiconductor devices keeps scaling down in size, three-dimensional multi-gate structures, such as the fin-type field effect transistor (FinFET), have been developed to replace planar Complementary Metal Oxide Semiconductor (CMOS) devices. A structural feature of the FinFET is the silicon-based fin that extends upright from the surface of the substrate, and the gate wrapping around the conducting channel that is formed by the fin further provides a better electrical control over the channel. Profiles of source/drain (S/D) and channel are critical for device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart illustrating a method for fabricating a FinFET in accordance with some embodiments.

FIGS. 2A-2M are perspective views of a method for fabricating a FinFET in accordance with some embodiments.

FIGS. 3A-3M are cross-sectional views of a method for fabricating a FinFET in accordance with some embodiments.

FIG. 4 is a top view of a semiconductor fin and a gate in a FinFET in accordance with some embodiments.

FIG. 5 is a perspective view of a FinFET in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The embodiments of the present disclosure describe the exemplary manufacturing process of FinFETs and the FinFETs fabricated there-from. The FinFET may be formed on bulk silicon substrates in certain embodiments of the present disclosure. Still, the FinFET may be formed on a silicon-on-insulator (SOI) substrate, a germanium-on-insulator (GUI) substrate, a SiGe substrate or a Group III-V semiconductor substrate as alternatives, Also, in accordance with the embodiments, the silicon substrate may include other conductive layers or other semiconductor elements, such as transistors, diodes or the like. The embodiments are not limited in this context.

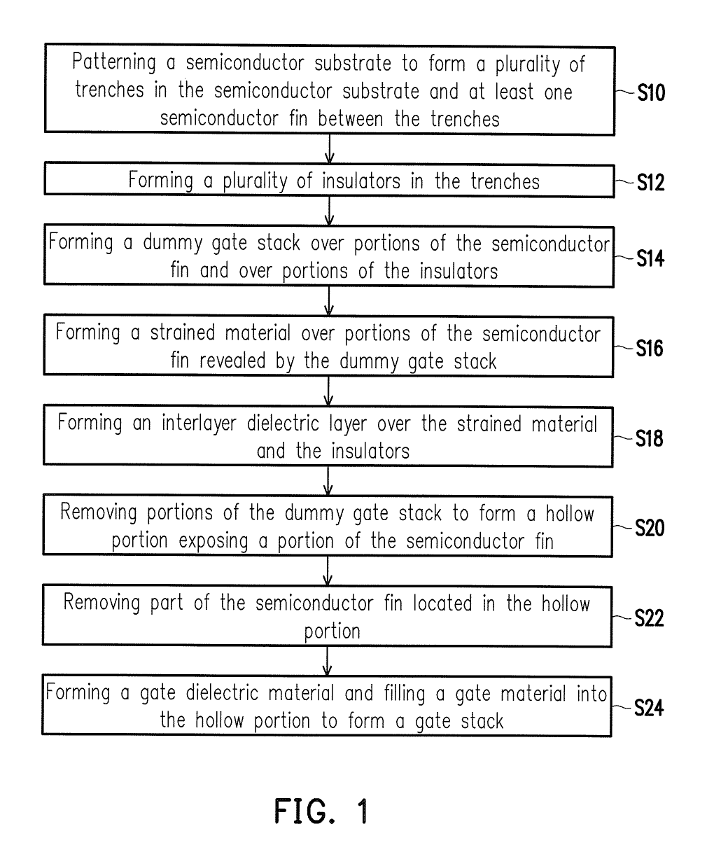

Referring to FIG. 1, illustrated is a flow chart illustrating a method for fabricating a FinFET in accordance with some embodiments of the present disclosure. The method at least includes steps S10, step S12, step S14, step S16, step S18, step S20, step S22, and step S24. First, in step S10, a semiconductor substrate is patterned to form a plurality of trenches in the semiconductor substrate and at least one semiconductor fin between the trenches. Then, in step S12, insulators are formed on the semiconductor substrate and located in the trenches. The insulators are shallow trench isolation (STI) structures for insulating or isolating the semiconductor fins, for example. Thereafter, in step S14, a dummy gate stack is formed over portions of the semiconductor fin and over the insulators. Subsequently, in step S16, a strained material (or a high doped low resistance material) is formed to cover the semiconductor fin revealed by the dummy gate stack. Then, in step S18, an interlayer dielectric layer is formed over the strained material and the insulators. Thereafter, in step S20, portions of the dummy gate stack are removed to form a hollow portion which exposes a portion of the semiconductor fin. Afterwards, in step S22, part of the semiconductor fin located in the hollow portion is removed. Subsequently, a gate dielectric material and a gate material are filled in the hollow portion to render a gate stack, as illustrated in step S24. As illustrated in FIG. 1, the strained material portions are formed after formation of the dummy gate stack. However, formation sequence of the dummy gate stack (step S14) and the strained material (step S16) is not limited in the present disclosure.

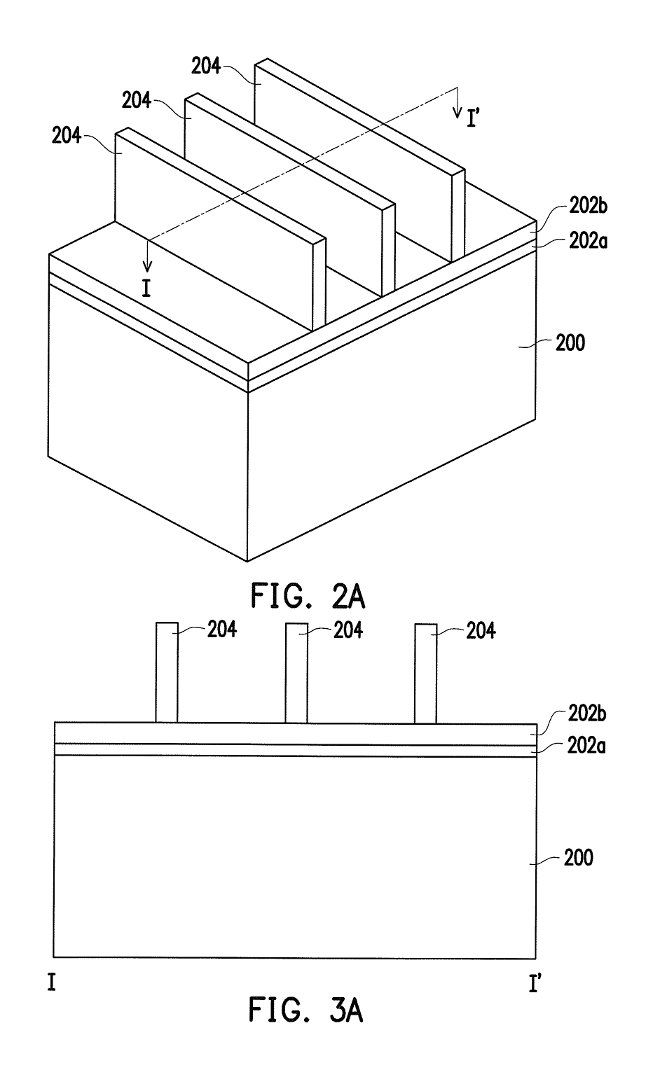

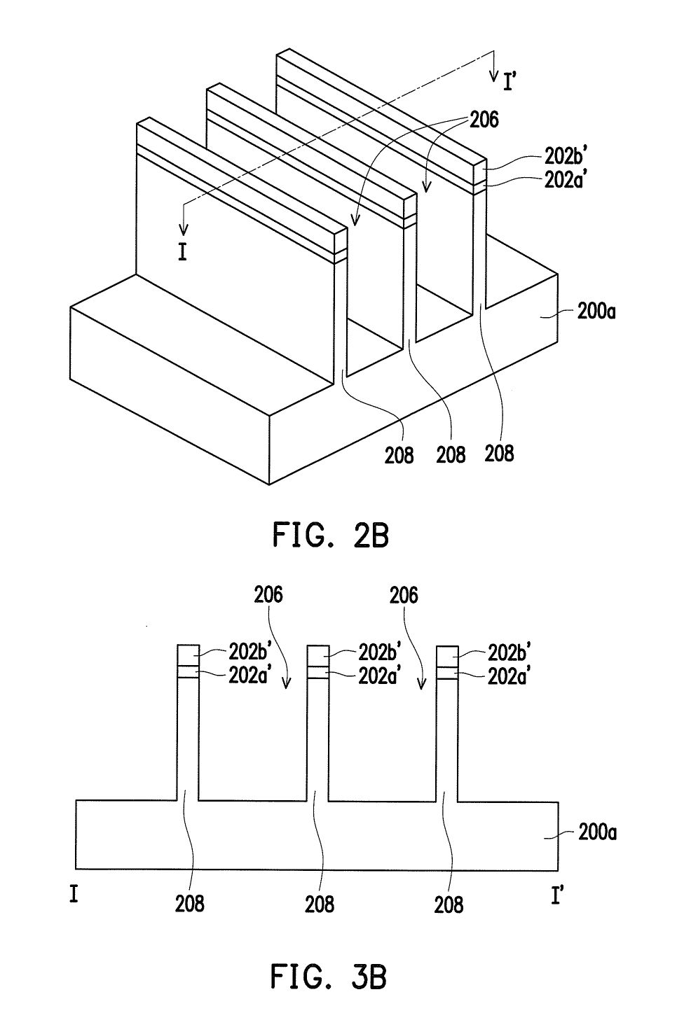

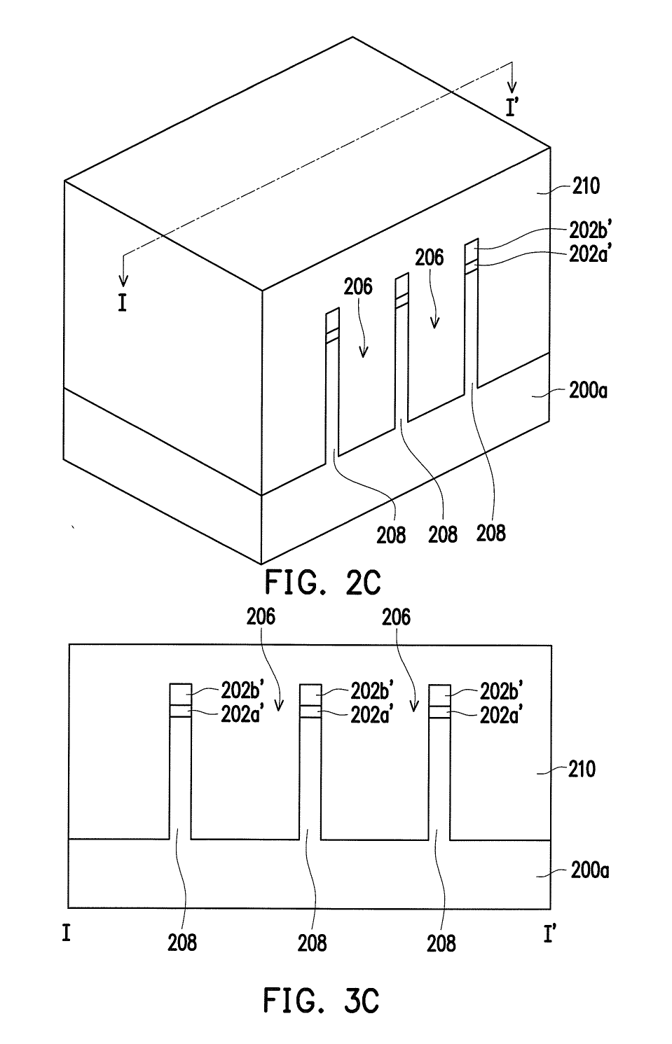

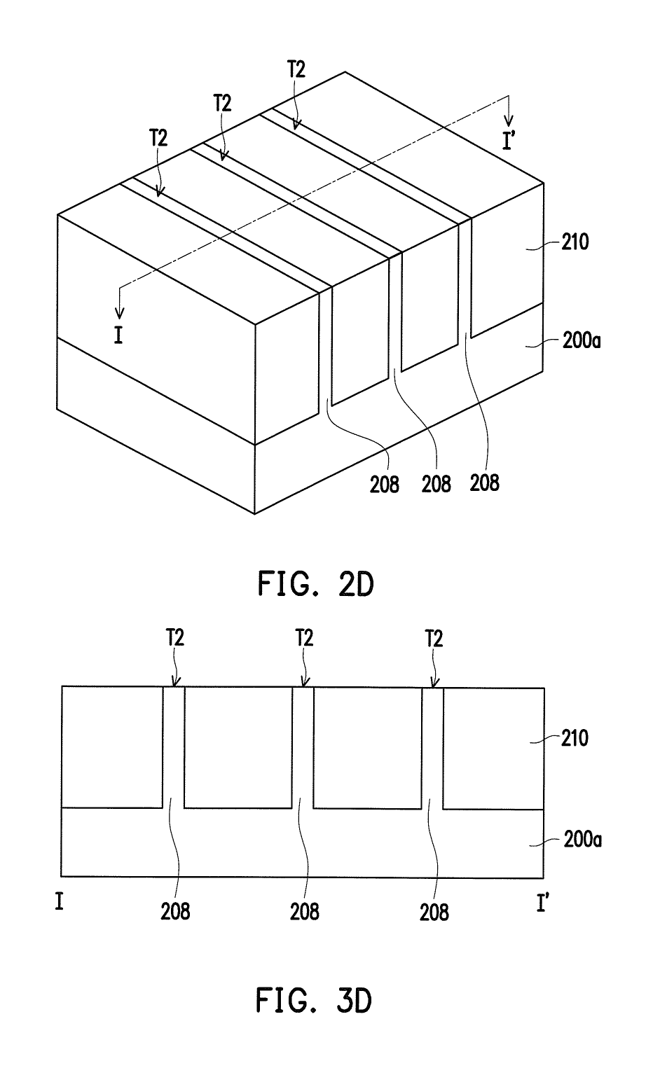

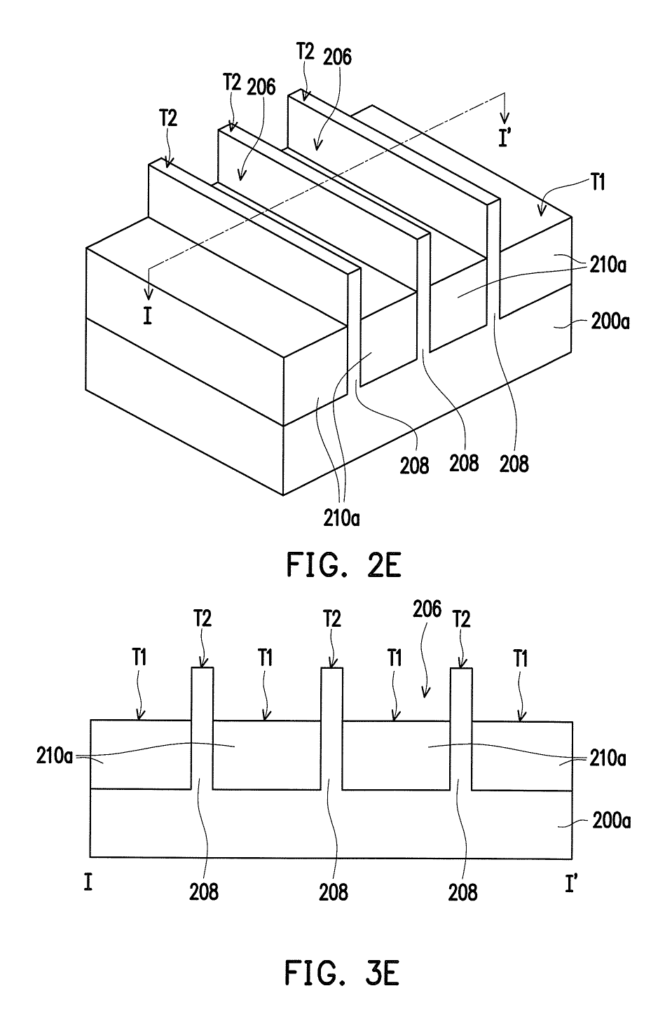

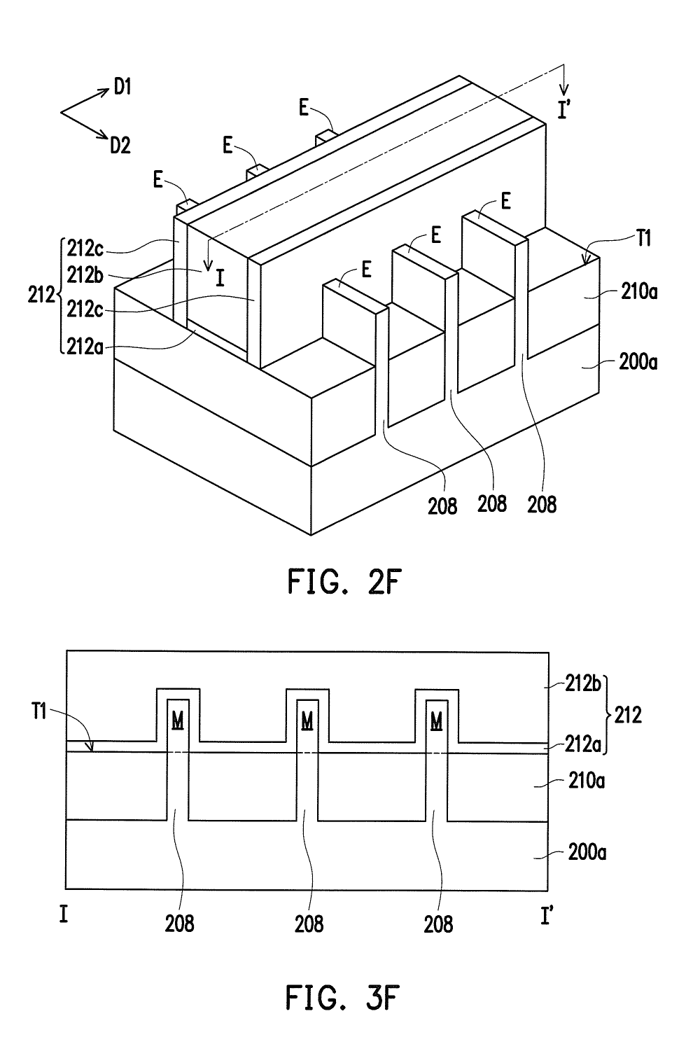

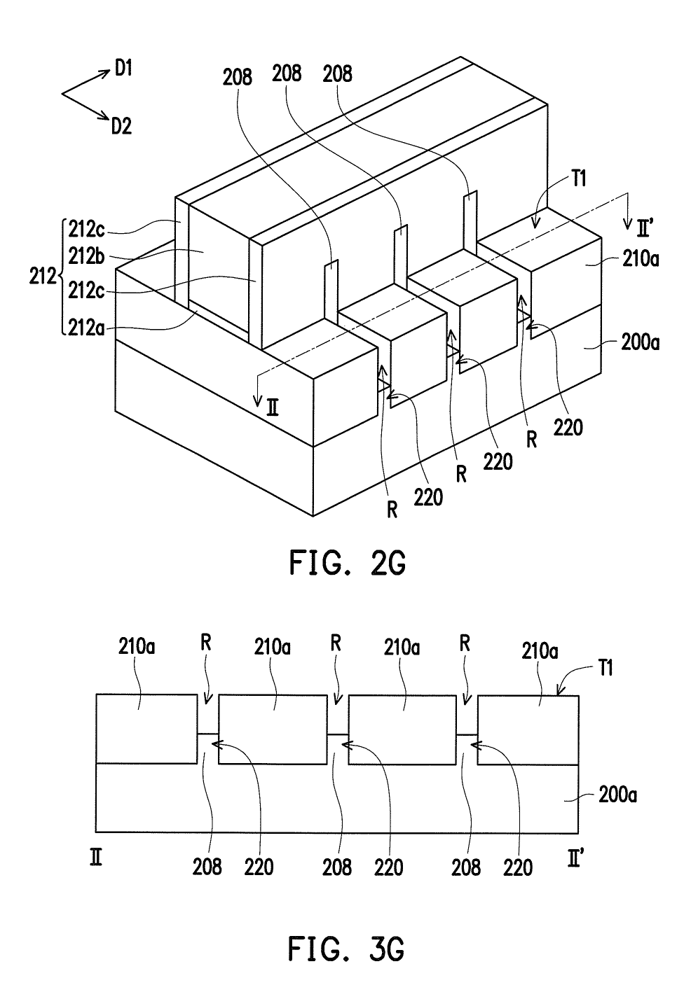

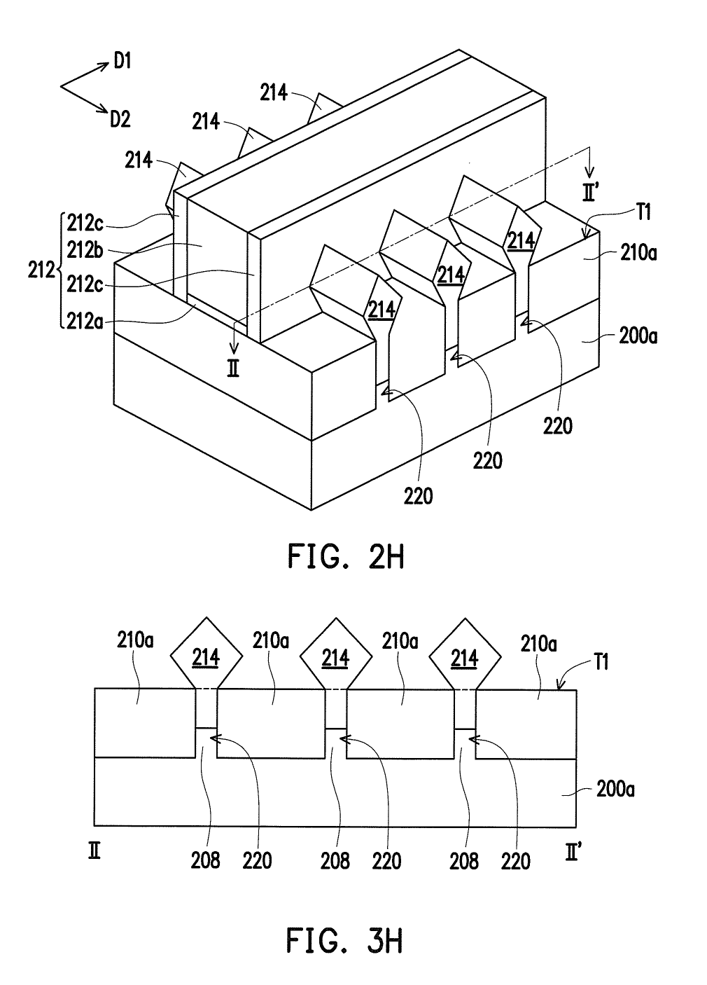

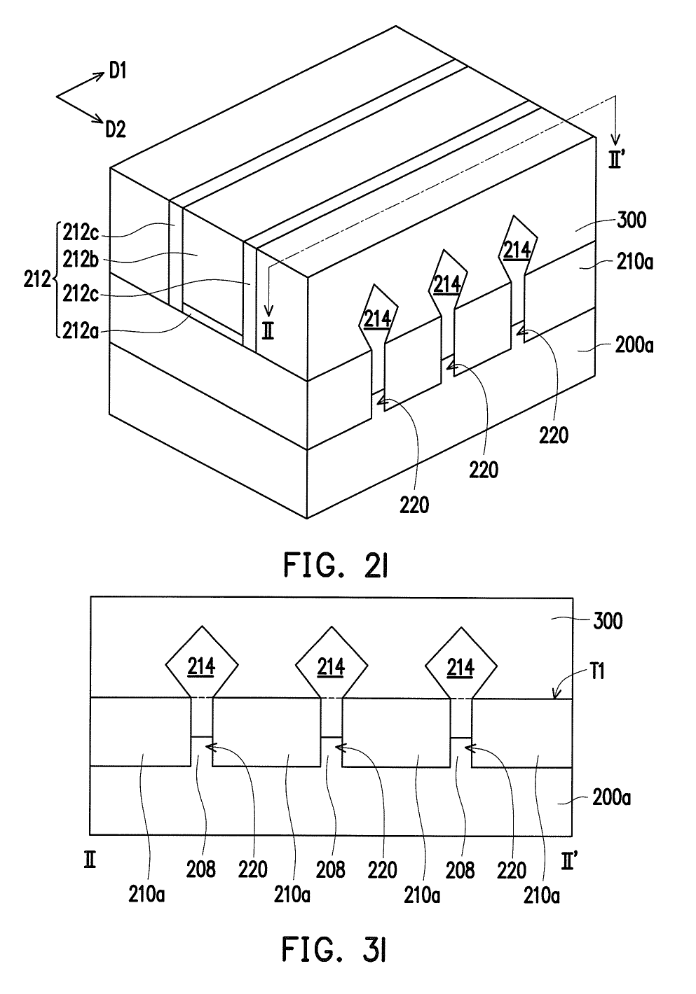

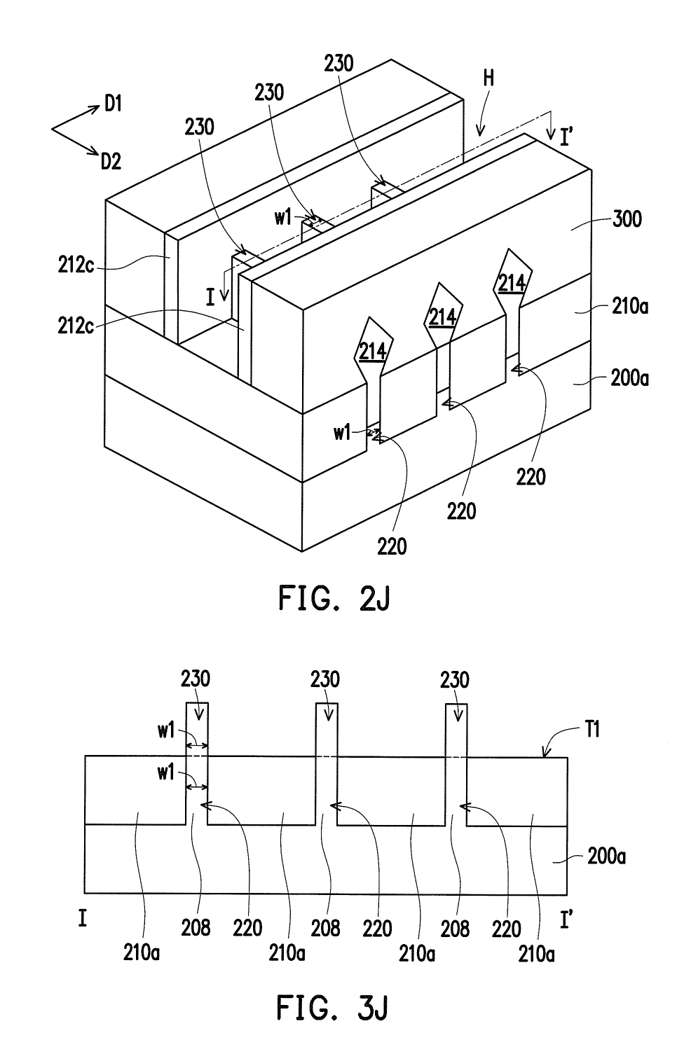

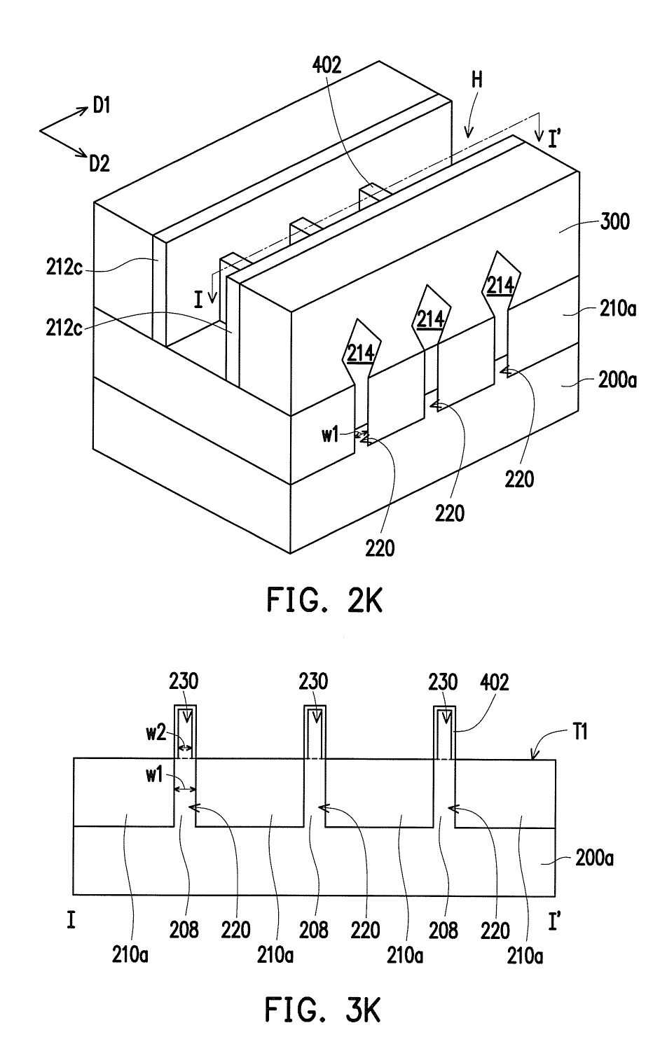

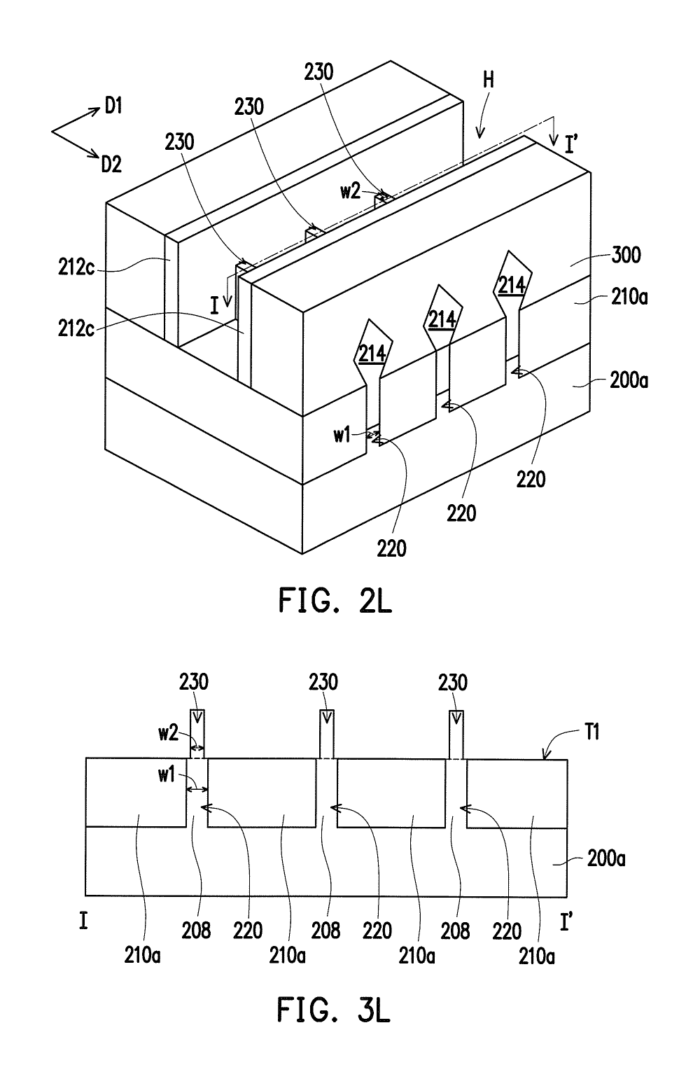

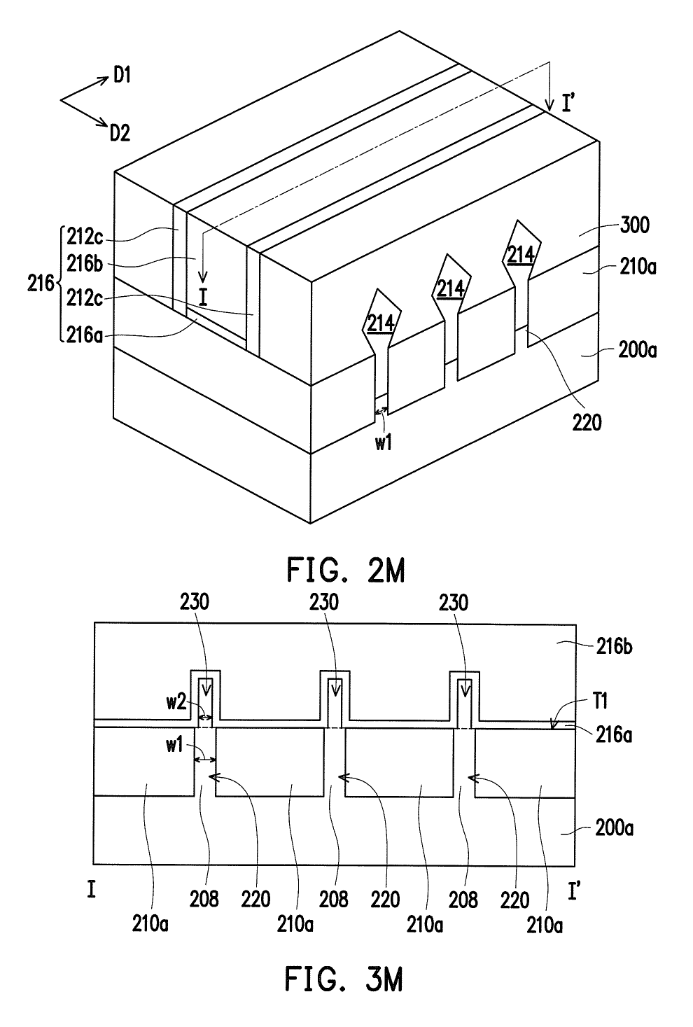

FIG. 2A is a perspective view of the FinFET at one of various stages of the manufacturing method, and FIG. 3A is a cross-sectional viewof the FinFET taken along the line I-I′ of FIG. 2A. In Step 10 in FIG. 1 and as shown in FIG. 2A and FIG. 3A, a semiconductor substrate 200 is provided. In one embodiment, the semiconductor substrate 200 comprises a crystalline silicon substrate (e.g., wafer). The semiconductor substrate 200 may comprise various doped regions depending on design requirements (e.g., p-type semiconductor substrate or n-type semiconductor substrate). In some embodiments, the doped regions may be doped with p-type or n-type dopants. For example, the doped regions may be doped with p-type dopants, such as boron or BF₂; n-type dopants, such as phosphorus or arsenic; and/or combinations thereof. The doped regions may be configured for an n-type FinFET, or alternatively configured for a p-type FinFET. In some alternative embodiments, the semiconductor substrate 200 may be made of some other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide.

In one embodiment, a pad layer 202a and a mask layer 202b are sequentially formed on the semiconductor substrate 200. The pad layer 202a may be a silicon oxide thin film formed, for example, by thermal oxidation process. The pad layer 202a may act as an adhesion layer between the semiconductor substrate 200 and mask layer 202b. The pad layer 202a may also act as an etch stop layer for etching the mask layer 202b. In at least one embodiment, the mask layer 202b is a silicon nitride layer formed, for example, by low-pressure chemical vapor deposition (LPCVD) or plasma enhanced chemical vapor deposition (PECVD). The mask layer 202b is used as a hard mask during subsequent photolithography processes. A patterned photoresist layer 204 having a predetermined pattern is formed on the mask layer 202b.

FIG. 2B is a perspective view of the FinFET at one of various stages of the manufacturing method, and FIG. 3B is a cross-sectional view of the FinFET taken along the line I-I′ of FIG. 2B. In Step S10 in FIG. 1 and as shown in FIGS. 2A-2B and FIGS. 3A-3B, the mask layer 202b and the pad layer 202a which are not covered by the patterned photoresist layer 204 are sequentially etched to form a patterned mask layer 202b′ and a patterned pad layer 202a′ so as to expose underlying semiconductor substrate 200. By using the patterned mask layer 202b′, the patterned pad layer 202a′ and the patterned photoresist layer 204 as a mask, portions of the semiconductor substrate 200 are exposed and etched to form trenches 206 and semiconductor fins 208. The semiconductor fins 208 are covered by the patterned mask layer 202b′, the patterned pad layer 202a′ and the patterned photoresist layer 204. Two adjacent trenches 206 are spaced apart by a spacing. For example, the spacing between trenches 206 may be smaller than about 30 nm. In other words, two adjacent trenches 206 are spaced apart by a corresponding semiconductor fin 208.

The height of the semiconductor fins 208 and the depth of the trench 206 range from about 5 nm to about 500 nm. After the trenches 206 and the semiconductor fins 208 are formed, the patterned photoresist layer 204 is then removed. In one embodiment, a cleaning process may be performed to remove a native oxide of the semiconductor substrate 200a and the semiconductor fins 208. The cleaning process may be performed using diluted hydrofluoric (DHF) acid or other suitable cleaning solutions.

FIG. 2C is a perspective view of the FinFET at one of various stages of the manufacturing method, and FIG. 3C is a cross-sectional view of the FinFET taken along the line I-I′ of FIG. 2C. In Step S12 in FIG. 1 and as shown in FIGS. 2B-2C and FIG. 3B-3C, an insulating material 210 is formed over the semiconductor substrate 200a to cover the semiconductor fins 208 and fill up the trenches 206. In addition to the semiconductor fins 208, the insulating material 210 further covers the patterned pad layer 202a′ and the patterned mask layer 202b′. The insulating material 210 may include silicon oxide, silicon nitride, silicon oxynitride, a spin-on dielectric material, or a low-K dielectric material. It should be noted that the low-K dielectric materials are generally dielectric materials having a dielectric constant lower than 3.9. The insulating material 210 may be formed by high-density-plasma chemical vapor deposition (HDP-CVD), sub-atmospheric CVD (SACVD) or by spin-on.

FIG. 2D is a perspective view of the FinFET at one of various stages of the manufacturing method, and FIG. 3D is a cross-sectional view of the FinFET taken along the line I-I′ of FIG. 2D. In Step S12 in FIG. 1 and as shown in FIGS. 2C-2D and FIGS. 3C-3D, a chemical mechanical polish (CMP) process and a wet etching process are, for example, performed to remove a portion of the insulating material 210, the patterned mask layer 202b′ and the patterned pad layer 202a′ until the semiconductor fins 208 are exposed. As shown in FIG. 2D and FIG. 3D, after the insulating material 210 is polished, top surfaces of the polished insulating material 210 is substantially coplanar with top surface T2 of the semiconductor fins 208.

FIG. 2E is a perspective view of the FinFET at one of various stages of the manufacturing method, and FIG. 3E is a cross-sectional view of the FinFET taken along the line I-I′ of FIG. 2E. In Step S12 in FIG. 1 and as shown in FIGS. 2D-2E and FIGS. 3D-3E, the polished insulating material 210 filled in the trenches 206 is partially removed by an etching process such that insulators 210a are formed on the semiconductor substrate 200a and each insulator 210a is located between two adjacent semiconductor fins 208. In one embodiment, the etching process may be a wet etching process with hydrofluoric acid (HF) or a dry etching process. The top surfaces T1 of the insulators 210a are lower than the top surfaces T2 of the semiconductor fins 208. The semiconductor fins 208 protrude from the top surfaces T1 of the insulators 210a. The height difference between the top surfaces T2 of the semiconductor fins 208 and the top surfaces T1 of the insulators 210a ranges from about 15 nm to about 50 nm.

FIG. 2F is a perspective view of the FinFET at one of various stages of the manufacturing method, and FIG. 3F is a cross-sectional view of the FinFET taken along the line I-I′ of FIG. 2F. In Step S14 in FIG. 1 and as shown in FIGS. 2E-2F and FIGS. 2F-3F, a dummy gate stack 212 is formed over portions of the semiconductor fins 208 and portion of the insulators 210a. In one embodiment, the extending direction D1 of the dummy gate stack 212 is, for example, perpendicular to the extension direction D2 of the semiconductor fins 208 so as to cover the middle portions M (shown in FIG. 3F) of the semiconductor fins 208. The dummy gate stack 212 comprises a dummy gate dielectric layer 212a and a dummy gate 212b disposed over the dummy gate dielectric layer 212a. The dummy gate 212b is disposed over portions of the semiconductor fins 208 and over portions of the insulators 210a. According to some embodiments, after the semiconductor fins 208 (as shown in FIG. 2E), the dummy gate dielectric layer 212a is formed to separate the semiconductor fins 208 and the dummy gate 212b and to function as an etching stop layer.

The dummy gate dielectric 212a is formed to cover the middle portions M of the semiconductor fins 208. In some embodiments, the dummy gate dielectric layer 212a may include silicon oxide, silicon nitride, or silicon oxy-nitride The dummy gate dielectric layer 212a may be formed using a suitable process such as atomic layer deposition (ALD), chemical vapor deposition (CVD), physical vapor deposition (PVD), thermal oxidation, UV-ozone oxidation, or combinations thereof.

The dummy gate 212b is then formed on the dummy gate dielectric layer 212a. In some embodiments, the dummy gate 212b may comprise a single layer or multi-layered structure. In some embodiments, the dummy gate 212b includes a silicon-containing material, such as poly-silicon, amorphous silicon or a combination thereof, and is formed prior to the formation of the strained material 214. In some embodiments, the dummy gate 212b comprises a thickness in the range of about 30 nm to about 90 nm. The dummy gate 212b may be formed using a suitable process such as ALD, CVD, PVD, plating, or combinations thereof.

In addition, the dummy gate stack 212 may further comprise a pair of spacers 212c disposed on sidewalls of the dummy gate dielectric layer 212a and the dummy gate 212b. The pair of spacer 212c may further cover portions of the semiconductor fins 208. The spacers 212c are formed of dielectric materials, such as silicon oxide, silicon nitride, carbonized Silicon nitride (SiCN), SiCON, or a combination thereof. The spacers 212c may include a single layer or multilayer structure. Portions of the semiconductor fins 208 that are not covered by the gate stack 212 are referred to as exposed portions E hereinafter.

FIG. 2G is a perspective view of the FinFET at one of various stages of the manufacturing method, and FIG. 3G is a cross-sectional view of the FinFET taken along the line II-II′ of FIG. 2G. In Step S16 in FIG. 1 and as shown in FIGS. 2F-2G and FIGS. 3F-3G, the exposed portions E of the semiconductor fins 208 are removed and recessed to formed recessed portions R. For example, the exposed portions E are removed by anisotropic etching, isotropic etching or the combination thereof. In some embodiments, the exposed portions E of the semiconductor fins 208 are recessed below the top surfaces T1 of the insulators 210a. The depth of the recessed portions R is less than the thickness of the insulators 210a. In other words, the exposed portions E of the semiconductor fins 208 are not entirely removed, and the remaining semiconductor fins 208 located in the recessed portion R constitute the source/drain regions 220. As show in FIG. 2G and FIG. 3G, portions of the semiconductor fins 208 covered by the dummy gate stack 212 is not removed when the exposed portions E of the semiconductor fins 208 are recessed. The portions of the semiconductor fins 208 covered by the dummy gate stack 212 are exposed at sidewalls of the dummy gate stack 212.

FIG. 2H is a perspective view of the FinFET at one of various stages of the manufacturing method, and FIG. 3H is a cross-sectional view of the FinFET taken along the line II-II′ of FIG. 2H. In Step S16 in FIG. 1 and as shown in FIGS. 2G-2H and FIGS. 2G-3H, a strained material 214 (or a high doped low resistance material) is grown over the recessed portions R of the semiconductor fin 208 and extends beyond the top surfaces T1 of the insulators 210a to strain or stress the semiconductor fins 208. In other words, the strained material 214 is formed over the source/drain regions 220 of the semiconductor fin 208. Thus, the strained material 214 comprises a source disposed at a side of the dummy stack gate 212 and a drain disposed at the other side of the dummy gate stack 212. The source covers an end of the semiconductor fins 208 and the drain covers the other end of the semiconductor fins 208.

The strained material 214 may be doped with a conductive dopant. In one embodiment, the strained material 214, such as SiGe, is epitaxial-grown with a p-type dopant for straining a p-type FinFET. That is, the strained material 214 is doped with the p-type dopant to be the source and the drain of the p-type FinFET. The p-type dopant comprises boron or BF₂, and the strained material 214 may be epitaxial-grown by LPCVD process with in-situ doping. In another embodiment, the strained material 214, such as SiC, SiP, a combination of SiC/SiP, or SiCP is epitaxial-grown with an n-type dopant for straining an n-type FinFET. That is, the strained material 214 is doped with the n-type dopant to be the source and the drain of the n-type FinFET. The n-type dopant comprises arsenic and/or phosphorus, and the strained material 214 may be epitaxial-grown by LPCVD process with in-situ doping. The strained material 214 may be a single layer or a multi-layer.

FIG. 2I is a perspective view of the FinFET at one of various stages of the manufacturing method, and FIG. 3I is a cross-sectional view of the FinFET taken along the line II-II′ of FIG. 2I. In Step S18 in FIG. 1 and as shown in FIG. 2I and FIG. 3I, an interlayer dielectric layer 300 is formed over the strained material 214 and the insulators 210a. In other words, the interlayer dielectric layer 300 is formed adjacent to the spacers 212c. The interlayer dielectric layer 300 includes silicon oxide, silicon nitride, silicon oxynitride, phosphosilicate glass (PSG), borophosphosilicate glass (BPSG), spin-on glass (SOG), fluorinated silica glass (FSG), carbon doped silicon oxide (e.g., SiCOH), polyimide, and/or a combination thereof. In some other embodiments, the interlayer dielectric layer 300 includes low-K dielectric materials. Examples of low-K dielectric materials include BLACK DIAMOND® (Applied Materials of Santa Clara, Calif.), Xerogel, Aerogel, amorphous fluorinated carbon, Parylene, BCB (bis-benzocyclobutenes), Flare, SILK® (Dow Chemical, Midland, Mich.), hydrogen silsesquioxane (HSQ) or fluorinated silicon oxide (SiOF), and/or a combination thereof. It is understood that the interlayer dielectric layer 300 may include one or more dielectric materials and/or one or more dielectric layers. In some embodiments, the interlayer dielectric layer 300 is formed to a suitable thickness by Flowable CVD (FCVD), CVD, HDPCVD, SACVD, spin-on, sputtering, or other suitable methods. Specifically, an interlayer dielectric material layer (not illustrated) is formed to cover the insulators 210a and the dummy gate stack 212 first. Subsequently, the thickness of the interlayer dielectric material layer is reduced until a top surface of the dummy gate stack 212 is exposed, so as to form the interlayer dielectric layer 300. The process of reducing the thickness of the interlayer dielectric material layer is achieved by a chemical mechanical polishing (CMP) process, an etching process, or other suitable process.

FIG. 2J is a perspective view of the FinFET at one of various stages of the manufacturing method, and FIG. 3J is a cross-sectional view of the FinFET taken along the line I-I′ of FIG. 2J. In Step S20 in FIG. 1 and as shown in FIG. 2J and FIG. 3J, portions of the dummy gate stack 212 is removed to form a hollow portion H exposing a portion of the semiconductor fin 208. In detail, the dummy gate 212b and the dummy gate dielectric layer 212a are removed, and the hollow portion H exposes part of the middle portions M of the semiconductor fin 208. It should be noted that the semiconductor fin 208 exposed by the hollow portion H may act as a channel region 230.

In some embodiments, the dummy gate 212b and the dummy gate dielectric layer 212a are removed through an etching process or other suitable processes. For example, the dummy gate 212b and the dummy gate dielectric layer 212a may be removed through wet etching or dry etching. Example of wet etching includes chemical etching and example of dry etching includes plasma etching, but they construe no limitation in the present disclosure. Other commonly known etching method may also be adapted to perform the removal of the dummy gate 212b and the dummy gate dielectric layer 212a. It should be noted that at this stage, the semiconductor fin 208 has a substantially uniform thickness of w1. In other words, the width of the semiconductor fin 208 located in the hollow portion H and the width of the semiconductor fin 208 covered by the spacers 212c, the interlayer dielectric layer 300, and the strained material 214 are substantially the same. As illustrated in FIG. 2J, the width of the source/drain regions 220 of the semiconductor fin 208 is also w1.

FIG. 2K and FIG. 2L are perspective views of the FinFET at one of various stages of the manufacturing method, and FIG. 3K and FIG. 3L are respectively a cross-sectional view of the FinFET taken along the line I-I′ of FIG. 2K and FIG. 2L. In Step S22 in FIG. 1 and as shown in FIGS. 2K-2L and FIGS. 3K-3L, a portion of the channel regions 230 of the semiconductor fin 208 located in the hollow portion H is removed. In detail, as illustrated in FIGS. 2K and 3K, an oxidation treatment is performed on the channel region 230 of the semiconductor fin 208 exposed by the hollow portion H to form a sacrificial oxide layer 402. The oxidation treatment may be achieved by, for example, passing an oxygen-containing gas to the semiconductor fin 208 to oxidize surface of the semiconductor fin 208 exposed by the hollow portion H. In some embodiments, the oxygen-containing gas may include ozone (O₃), hydrogen peroxide (H₂O₂), or other suitable gas encompassing oxygen atoms. Specifically, after the oxygen-containing gas reaches surfaces of the channel region 230 of the semiconductor fin 208, the oxygen atoms in the gas would react with the elements of the semiconductor fin 208 to form oxides. For examples, if the material of the semiconductor fin 208 is silicon, the resulting sacrificial oxide layer 402 may include silicon dioxide. It should be noted that since the oxidation treatment is a dry treatment, the removal of the dummy gate dielectric layer 212a and the oxidation treatment of the semiconductor fin 208 may be accomplished through an in-situ process. In other words, if the removal of the dummy gate dielectric layer 212a is performed through dry etching, the removal process and the oxidation treatment are in-situ processes and may be performed at a single chamber.

After the surfaces of the semiconductor fins 208 are oxidized to form sacrificial oxide layer 402, the sacrificial oxide layer 402 is removed to obtain a thinner channel region 230, as shown in FIG. 2L and FIG. 3L. In some embodiments, the removal of the sacrificial oxide layer 402 may be performed using diluted hydrofluoric (DHF) acid or other suitable solutions. It should be noted that since part of the semiconductor fin 208 exposed by the hallow portion H is converted into sacrificial oxide layer 402 and is subsequently removed, a width w2 of the channel regions 230 is smaller the width w1 of the source/drain region 220 of the semiconductor fin 208.

FIG. 2M is a perspective view of the FinFET at one of various stages of the manufacturing method, and FIG. 3M is a cross-sectional view of the FinFET taken along the line I-I′ of FIG. 2M. In Step S22 in FIG. 1 and as shown in FIG. 2M and FIG. 3M, a gate dielectric material and a gate material are filled into the hollow portion H to form a gate stack 216. Specifically, the gate stack 216 includes a gate dielectric layer 216a, a gate 216b, and spacers 212c. The gate dielectric layer 216a is disposed over the channel region 230 of the semiconductor fin 208, the gate 216b is disposed over the gate dielectric layer 216a, and the spacers 213c are disposed on sidewalls of the gate dielectric layer 216a and the gate 216b. A material of the gate dielectric layer 216a may be identical to or different from the material of the dummy gate dielectric layer 212a. For example, the gate dielectric layer 216a includes silicon oxide, silicon nitride, silicon oxy-nitride, high-K dielectric materials, or a combination thereof. High-K dielectric materials include metal oxides such as oxides of Li, Be, Mg, Ca, Sr, Sc, Y, Zr, Hf, Al, La, Ce, Pr, Nd, Sm, Eu, Gd, Tb, Dy, Ho, Er, Tm, Yb, Lu, and/or a combination thereof. In some embodiments, the gate dielectric layer 216a has a thickness in the range of about 10 to 30 angstroms. The gate dielectric layer 216a is formed using a suitable process such as atomic layer deposition (ALD), chemical vapor deposition (CVD), physical vapor deposition (PVD), flowable chemical vapor deposition (FCVD), thermal oxidation, UV-ozone oxidation, or a combination thereof. The gate dielectric layer 216a may further comprise an interfacial layer (not shown). For example, the interfacial layer may be used in order to create a good interface between the semiconductor fin 208 and the gate 216b, as well as to suppress the mobility degradation of the channel carrier of the semiconductor device. Moreover, the interfacial layer is formed by a thermal oxidation process, a chemical vapor deposition (CVD) process, or an atomic layer deposition (ALD) process. A material of the interfacial layer includes a dielectric material, such as a silicon oxide layer or a silicon oxynitride layer.

A material of the gate 216b includes metal, metal alloy, or metal nitride. For example, in some embodiments, the gate 216b may include TiN, WN, TaN, Ru, Ti, Ag, Al, TiAl, TiAlN, TaC, TaCN, TaSiN, Mn, or Zr. Moreover, the gate 216b may further include a barrier, a work function layer, or a combination thereof. As mentioned above, an interfacial layer may be included between the gate 216b and the semiconductor fin 208, but it construes no limitation to the present disclosure. In some alternative embodiments, a liner layer, a seed layer, an adhesion layer, or a combination thereof may also be included between the gate 216b and the semiconductor fin 208. The process illustrate in step S22 in FIG. 1 is commonly referred as metal replacement process. Specifically, in some embodiments, the dummy gate stack 212 including polysilicon is replaced by gate stack 216 which includes metal. Since the dummy gate stack 212 are being replaced by the gate stack 216, subsequent process of forming metallic interconnection (not illustrated) can be implemented. For instance, other conductive lines (not illustrate) are formed to electrically connect the gate 216b with other elements in the semiconductor device.

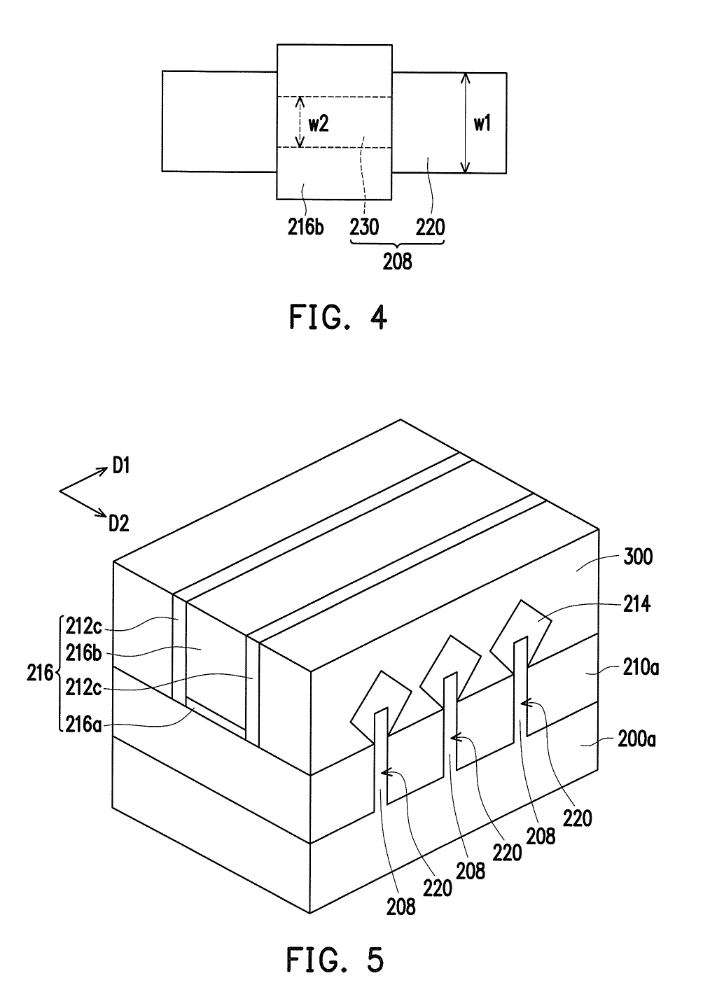

FIG. 4 is a top view of a semiconductor fin and a gate in a FinFET in accordance with some embodiments. It should be noted that in order to clearly illustrate the relationship between the gate 216b and the semiconductor fin 208, only these two elements are illustrated in FIG. 4 and other components in the FinFET are omitted. As mentioned above, since the channel regions 230 of the semiconductor fin 208 exposed by the hollow portion H (as shown in FIG. 2J to FIG. 2K) is subjected to oxidation treatment, the width w1 of the source/drain regions 220 of the semiconductor fin 208 is greater than the width w2 of the channel region 230 of the semiconductor fin 208. In other words, each of the semiconductor fin 208 in the FinFET exhibits a dog-bone shape, as illustrated in FIG. 4. In some embodiments, the larger width w1 of the source/drain region 220 permits a larger size of the strained material 214, thereby enhancing the performance of the device. Similarly, the smaller width w2 of the channel region 230 is beneficial to a better gate control, and thus may also contribute to the performance of the device. Moreover, since the gate 216b is filled into the hollow portion H (as shown in FIG. 2L to FIG. 3M), the gate 216b is aligned with the channel region 230 of the semiconductor fin 208. In other words, the gate 216b is self-aligned with the channel region 230 of the semiconductor fin 208, and thus the manufacturing process for the FinFET is more convenient.

FIG. 5 is a perspective view of a FinFET in accordance with some alternative embodiments. In the embodiment, the fabricating steps for the FinFET include performing the process steps the same with or similar to the steps showing in FIGS. 2A-2F, 2I-2M and FIGS. 3A-3F, 3I-3M. In other words, the step of forming recessed portion R is omitted in some embodiments. In this case, the semiconductor fin 208 in the FinFET also exhibits a dog-bone shape, and thus the device performance can be enhanced, and self-alignment of the gate 216b may be achieved.

In accordance with some embodiments of the present disclosure, a method of fabricating a FinFET includes at least the following steps. A semiconductor substrate is patterned to form a plurality of trenches in the semiconductor substrate and at least one semiconductor fin between the trenches. A plurality of insulators are formed in the trenches. A dummy gate stack is formed over portions of the semiconductor fin and over portions of the insulators. A strained material is formed over portions of the semiconductor fin revealed by the dummy gate stack. Portions of the dummy gate stack are removed to form a hollow portion exposing a portion of the semiconductor fin. Part of the semiconductor fin located in the hollow portion is removed. A gate dielectric material and a gate material are filled into the hollow portion to form a gate stack.

In accordance with some embodiments of the present disclosure, a method of fabricating a FinFET includes at least the following steps. A semiconductor substrate is patterned to form a plurality of trenches in the semiconductor substrate and at least one semiconductor fin between the trenches. A plurality of insulators are formed in the trenches. A dummy gate stack is formed over portions of the semiconductor fin and over portions of the insulators to expose source/drain regions of the semiconductor fin, and the dummy gate stack includes a dummy gate, a dummy gate dielectric layer, and a plurality of spacers. A strained material is formed over the source/drain regions of the semiconductor fin. The dummy gate dielectric layer and the dummy gate are removed to expose a channel region of the semiconductor fin. A portion of the channel region of the semiconductor fin is removed. A gate dielectric material and a gate material are formed over the channel region of the semiconductor fin to form a gate stack.

In accordance with some embodiments of the present disclosure, a FinFET includes a semiconductor substrate, a plurality of insulators, a gate stack, and a strained material. The semiconductor substrate includes at least one semiconductor fin thereon. The semiconductor fin includes source/drain regions and a channel region, and a width of the source/drain regions is larger than a width of the channel region. The insulators are disposed on the semiconductor substrate and the semiconductor fin being sandwiched by the insulators. The gate stack is located over the channel region of the semiconductor fin and over portions of the insulators. The strained material covers the source/drain regions of the semiconductor fin.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a fin field effect transistor (FinFET), comprising:
patterning a semiconductor substrate to form a plurality of trenches in the semiconductor substrate and at least one semiconductor fin between the trenches;
forming a plurality of insulators in the trenches;
forming a dummy gate stack over portions of the semiconductor fin and over portions of the insulators;
forming a strained material over portions of the semiconductor fin revealed by the dummy gate stack;
removing portions of the dummy gate stack to form a hollow portion exposing a portion of the semiconductor fin;
removing part of the semiconductor fin located in the hollow portion; and
forming a gate dielectric material and filling a gate material into the hollow portion to form a gate stack.

2. The method of claim 1, wherein the dummy gate stack comprises a dummy gate, a dummy gate dielectric layer, and a plurality of spacers, and the step of removing portions of the dummy gate stack and the step of removing part of the semiconductor fin located in the hollow portion comprise:
removing the dummy gate;
removing the dummy gate dielectric layer to expose the semiconductor fin;
performing an oxidation treatment on the exposed semiconductor fin to form a sacrificial oxide layer; and
removing the sacrificial oxide layer.

3. The method of claim 2, wherein:
the step of removing the dummy gate dielectric layer comprises performing a wet etching process; and
the step of performing the oxidation treatment comprises passing an oxygen-containing gas to oxidize surfaces of the semiconductor fin.

4. The method of claim 2, wherein:
the step of removing the dummy gate dielectric layer comprises performing a dry etching process; and
the step of performing the oxidation treatment comprises passing an oxygen-containing gas to oxidize surfaces of the semiconductor fin.

5. The method of claim 4, wherein the step of removing the dummy gate dielectric layer and the step of performing the oxidation treatment are in-situ processes.

6. The method of claim 1, further comprising:
removing the semiconductor fin revealed by the gate stack to form a recessed portion of the semiconductor fin, and the strained material is filled into the recessed portions to cover the semiconductor fin revealed by the dummy gate stack.

7. The method of claim 1, further comprising:
forming an interlayer dielectric layer over the strained material and the insulators, wherein the interlayer dielectric layer exposes the dummy gate stack.

8. A method of fabricating a fin field effect transistor (FinFET), comprising:
patterning a semiconductor substrate to form a plurality of trenches in the semiconductor substrate and at least one semiconductor fin between the trenches;
forming a plurality of insulators in the trenches;
forming a dummy gate stack over portions of the semiconductor fin and over portions of the insulators to expose source/drain regions of the semiconductor fin, wherein the dummy gate stack comprises a dummy gate, a dummy gate dielectric layer, and a plurality of spacers;
forming a strained material over the source/drain regions of the semiconductor fin;
removing the dummy gate and the dummy gate dielectric layer to expose a channel region of the semiconductor fin;
removing a portion of the channel region of the semiconductor fin; and
forming a gate dielectric material and a gate material over the channel region of the semiconductor fin to form a gate stack.

9. The method of claim 8, wherein the step of removing a portion of the channel region of the semiconductor fin comprises:
performing an oxidation treatment on the channel region of the semiconductor fin to form a sacrificial oxide layer; and
removing the sacrificial oxide layer.

10. The method of claim 9, wherein:
the step of removing the dummy gate dielectric layer comprises performing a wet etching process; and
the step of performing the oxidation treatment comprises passing an oxygen-containing gas to oxidize surfaces of the semiconductor fin.

11. The method of claim 9, wherein:
the step of removing the dummy gate dielectric layer comprises performing a dry etching process; and
the step of performing the oxidation treatment comprises passing an oxygen-containing gas to oxidize surfaces of the semiconductor fin.

12. The method of claim 11, wherein the step of removing the dummy gate dielectric layer and the step of performing the oxidation treatment are in-situ processes.

13. The method of claim 8, further comprising:
removing part of the semiconductor fin to form a recessed portion of the semiconductor fin, and the strained material is filled into the recessed portions to cover the source/drain regions of the semiconductor fin.

14. The method of claim 8, wherein a width of the source/drain regions of the semiconductor fin is greater than a width of the channel region of the semiconductor fin.

15. The method of claim 8, further comprising:
forming an interlayer dielectric layer over the strained material and the insulators, wherein the interlayer dielectric layer exposes the dummy gate stack.

16. A fin field effect transistor (FinFET), comprising:
a semiconductor substrate comprising at least one semiconductor fin thereon, wherein the semiconductor fin comprises source/drain regions and a channel region, and a width of the source/drain regions is larger than a width of the channel region;
a plurality of insulators disposed on the semiconductor substrate, the semiconductor fin being sandwiched by the insulators;
a gate stack over the channel region of the semiconductor fin and over portions of the insulators; and
a strained material covering the source/drain regions of the semiconductor fin.

17. The FinFet of claim 16, wherein the gate stack comprises:
a gate dielectric layer disposed over the channel region of the semiconductor fin;
a gate disposed over the gate dielectric layer; and
a plurality of spacers disposed on sidewalls of the gate dielectric layer and the gate.

18. The FinFet of claim 17, wherein a material of the gate comprises metal, metal alloy, or metal nitride.

19. The FinFET of claim 16, wherein the semiconductor fin further comprises a recessed portion, and the strained material fills into the recessed portion to cover the source/drain regions of the semiconductor fin.

20. The FinFET of claim 16, wherein the gate is aligned with the channel region of the semiconductor film.
